(19) United States
(12) Patent Application Publication
(10) Pub. No.: US 2026/0088377 A1
(43) Pub. Date: Mar. 26, 2026

(54) Interposer Accessory for Two Way Radios Providing External Regulated Power Output

(71) Applicant: Matthew Scott Gilliam, Los Angeles, CA (US)

(72) Inventor: Matthew Scott Gilliam, Los Angeles, CA (US)

(21) Appl. No.: 19/334,909

(22) Filed: Sep. 21, 2025

Related U.S. Application Data
(60) Provisional application No. 63/697,565, filed on Sep. 22, 2024.

(51) Int. Cl. H01M 10/46; G06F 13/38; G06F 13/42; H01M 10/48; H01M 50/247; H01R 31/06; H02J 7/00; H04B 1/40; H05K 5/02

(52) U.S. Cl. CPC H01M 10/46; G06F 13/382; G06F 13/4282; H01M 10/488; H01M 50/247; H01R 31/06; H02J 7/68; H02J 7/80; H02J 7/865; H05K 5/0247; G06F 2213/0042; H01M 2220/30; H04B 1/40

(57) ABSTRACT

An interposer accessory fits between a two-way radio and its removable battery and maintains pass-through power connections between them, with any auxiliary communication contact passed through without termination. Power-conversion circuitry provides at least one regulated external output, for example a 5 V USB output accessible from the housing. In some embodiments the interposer further includes a USB input interface configured to accept external power and charge the attached battery through a unidirectional and/or OR-ing arrangement. The accessory can retain the radio's form factor using tabs and a spring latch with a thumb release, and may include indicators that convey charge state at the housing. The interfaces can be dimensioned for different radio families while preserving the pass-through connections and external output. USB Power Delivery capability is optional.

### CROSS-REFERENCE TO RELATED APPLICATION

This application claims the benefit under 35 U.S.C. 119(e) of U.S. Provisional Application No. 63/697,565, filed Sep. 22, 2024. The entire contents of the provisional application are incorporated by reference herein.

### FIELD

The disclosure relates to two-way radios, and more particularly to accessories that mechanically and electrically interpose between a radio and its removable battery to provide additional power interfaces while preserving normal radio operation.

### BACKGROUND

Conventional two-way radios are commonly powered by detachable battery packs that latch to a radio body. Users increasingly carry mobile devices and tools that require regulated 5 V power (for example, USB). To charge or power such devices in the field, users often carry separate power banks or adapters, adding bulk and cable clutter.

Existing radio accessories typically occupy accessory ports or replace the battery entirely, which may compromise form factor, runtime, or compatibility. There remains a need for an accessory that fits between the radio and its removable battery pack, preserves the radio's power path and, where present, any auxiliary communication contact(s), and exposes at least one regulated external power output, optionally also accepting external power to charge the attached battery, without materially altering radio usability.

### SUMMARY

In one aspect, an interposer accessory fits between a two-way radio and its removable battery pack. The interposer includes mating interfaces with pass-through contacts that preserve the battery-to-radio power path and, in some embodiments, an auxiliary/communication contact without termination or conditioning. Power-conversion circuitry within the interposer provides a regulated external output, for example, a 5 V USB output accessible via a user receptacle. In some embodiments the interposer further includes a power input interface and a charge circuit configured to accept external power and deliver charging current to the attached battery through a unidirectional and/or OR-ing arrangement. Presence or absence of USB Power Delivery (PD) negotiation on any output is non-limiting.

The device may maintain the radio's mechanical latch functionality via tabs and a spring latch with thumb release. In some embodiments, indicators (for example, green and red LEDs) convey charge state at the housing. The interposer may be adapted to different radio models by dimensioning the first and second interfaces to the respective radio and battery geometries while preserving the pass-through contacts and external output.

### BRIEF DESCRIPTION OF THE DRAWINGS

FIG. 1 is an exploded perspective view from a battery-facing angle showing a radio body (10), the interposer housing (100), and a removable battery pack (20), including the interposer's battery-side interface (112).

FIG. 2 is an exploded perspective view from a radio-facing angle showing a radio body (10), the interposer housing (100), and a removable battery pack (20), including the interposer's radio-side interface (111).

FIG. 3 is an assembled perspective view of the interposer (100) installed between the radio body (10) and the removable battery pack (20).

FIG. 4 is a top orthographic view showing USB Type-C receptacles, namely a sink/input receptacle (152) and a source/output receptacle (156).

FIG. 5 is a perspective view from a battery-facing angle showing a spring latch/tongue (132) with integral thumb release (134), a USB Type-A receptacle (154), indicator apertures (182, 183), tabs (130), and battery-side contacts (122a, 122b, 122c).

FIG. 6 is a perspective view from a radio-facing angle showing radio-side contacts (120a, 120b, 120c), tabs (130), a thumb release (134), and a USB Type-A receptacle (154).

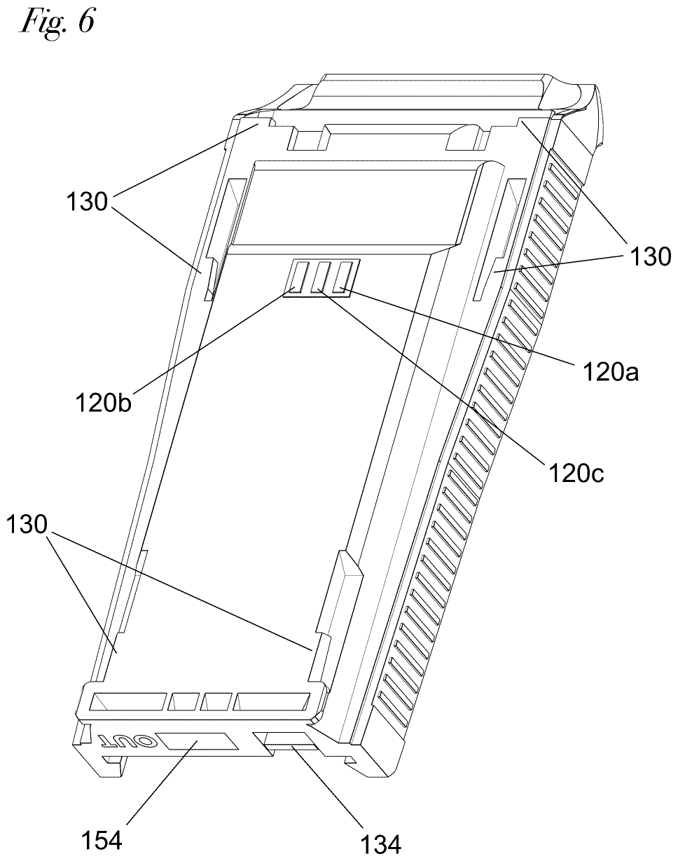

FIG. 7 is an electrical block diagram of the interposer architecture. Core elements include the pass-through power path (201) that couples the battery-side power contacts 122a (+VBAT) and 122b (GND) to the radio-side power contacts 120a (+VBAT) and 120b (GND), and an auxiliary/communication pass-through (202) that connects battery-side contact 122c to radio-side contact 120c without termination or conditioning. A buck converter (210) derives a regulated 5 V rail that feeds a USB-A output (node 214 to receptacle 154, with BC1.2 identification 213) and/or a USB-C source output (node 216 to receptacle 156, with Type-C CC pull-up (Rp) 212). Optional elements shown in dashed outline include a USB-C sink interface (node 220 to receptacle 152) supplying a generic constant-current/constant-voltage charger (230) whose output is coupled to the VBAT pass-through (201) through an ideal-diode or reverse-blocking stage (240) and an OR-ing element (242). Additional optional elements include protections (250), ESD arrays (252) at the receptacles, and an LED driver/resistor network (290) that drives indicators 180 (green) and 181 (red).

### DETAILED DESCRIPTION OF EXAMPLE EMBODIMENTS

### A. Mechanical Form and Interfaces

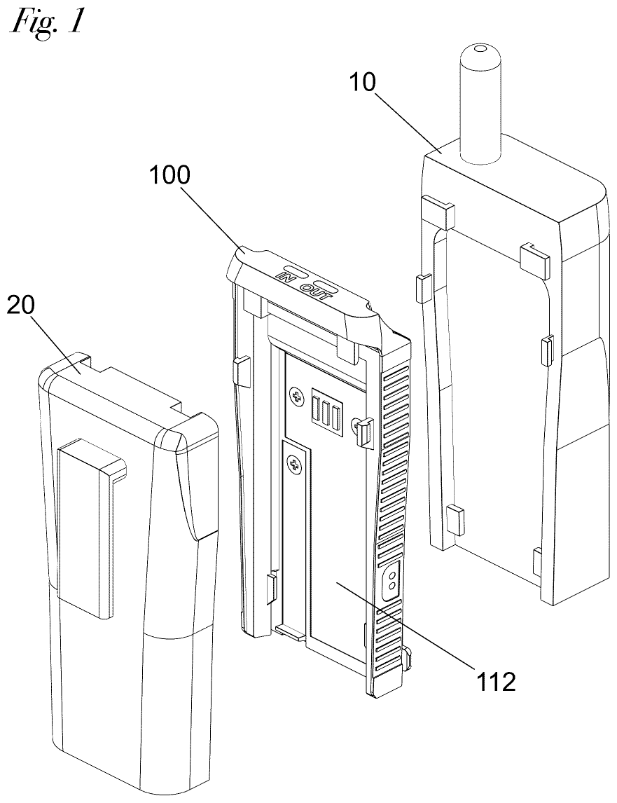

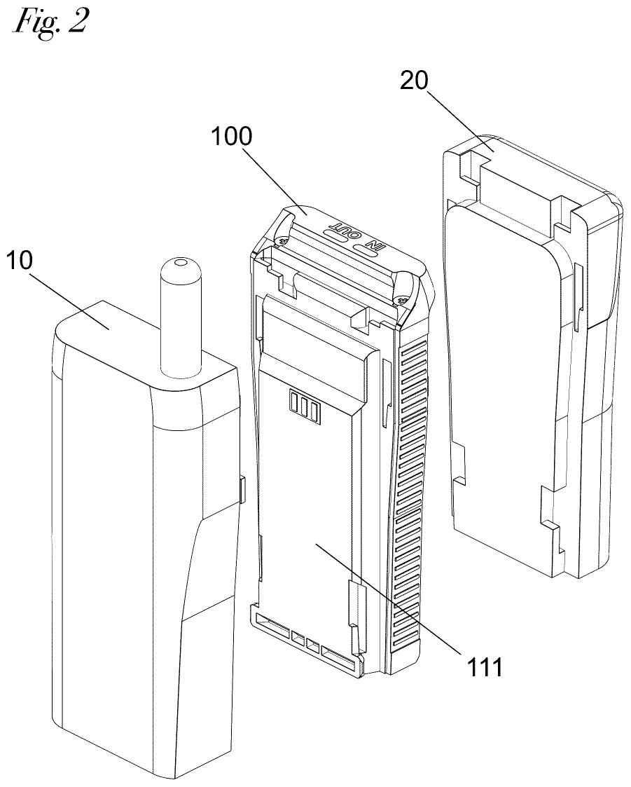

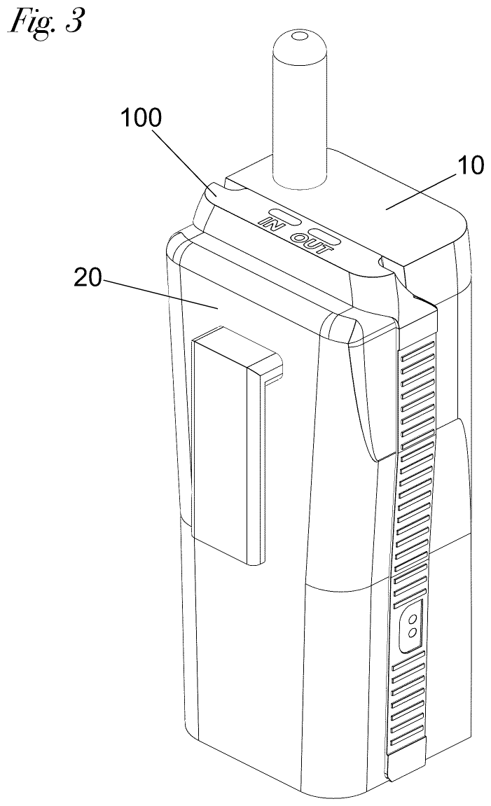

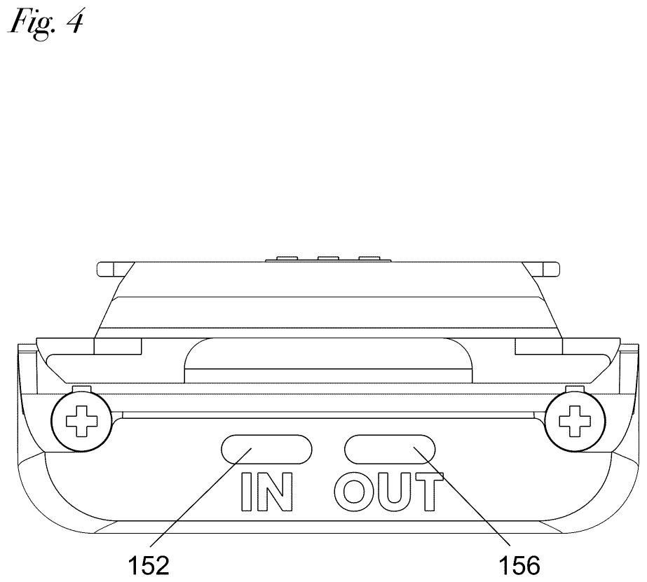

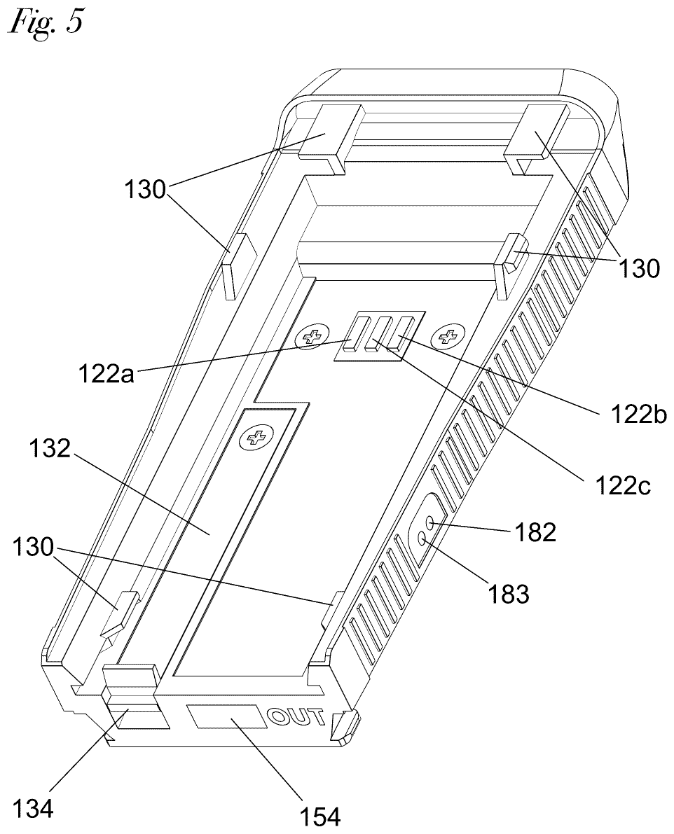

Referring to FIGS. 1-5, an interposer housing (100) is dimensioned to fit between a radio body (10) and a removable battery pack (20). A first interface (face 111) mates to the radio's battery-receiving interface and presents radio-facing contacts (120a/120b/120c) configured, for example, for +VBAT, GND, and an auxiliary/communication contact. A second interface (face 112) mates to the battery pack (20) and presents battery-facing contacts (122a/122b/122c) configured, for example, for +VBAT, GND, and AUX/COMM.

Alignment and retention features include tabs (130) and a spring latch/tongue (132) with an integral thumb release (134) that engages a cooperating recess or notch on the battery pack. The latch is deflected by thumb pressure to disengage. All tab/latch geometries shown are illustrative; equivalents such as alternative tab counts, orientations, snap-fits, adhesives, and fastener patterns may be used. Counts, positions, and geometries of tabs and latches are exemplary and non-limiting. Indicator apertures (182, 183) are located on a sidewall to convey light from internal indicator LEDs (180, 181) (green and red). Light conveyance may be direct view, a light pipe, a fiber, or a translucent housing region; any such approach is non-limiting.

The housing can be formed by additive manufacturing (for example, 3D printing), machining, or injection molding, and may be a single piece or multiple shells. Materials may include, for example, ABS, ASA, and aluminum. Dimensions are non-limiting; by way of example, a design may add approximately 12 mm of thickness compared to a stock battery, and may have overall dimensions of approximately 27 mm×61 mm×128 mm.

### B. Electrical Architecture

### B.1 Pass-Through Rails

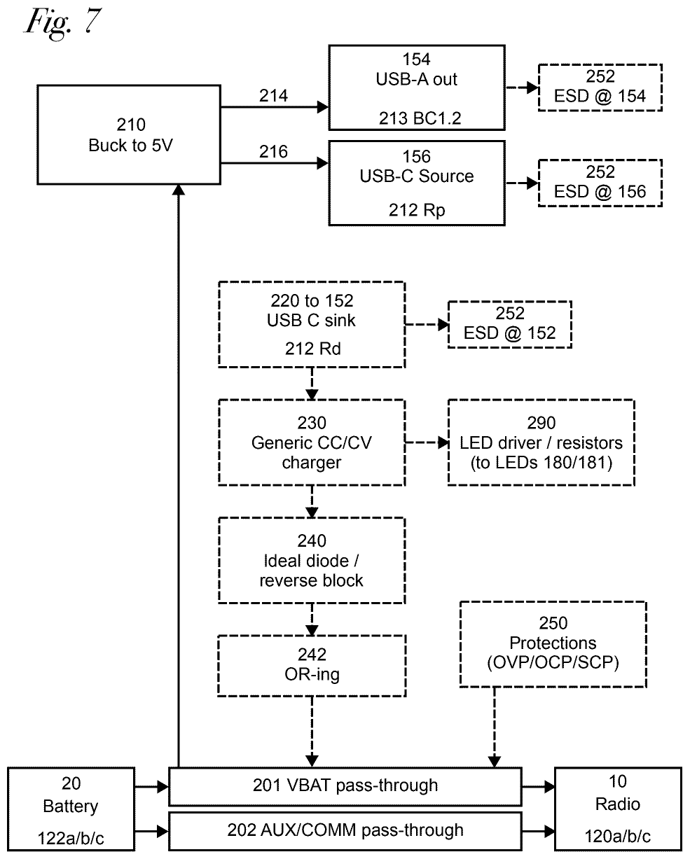

As shown in FIG. 7, conductive members establish a pass-through power path (201) coupling battery +VBAT/GND (122a/122b) to radio +VBAT/GND (120a/120b). An auxiliary/communication pass-through (202) connects 122c to 120c without termination, biasing, or signal conditioning by the interposer. The auxiliary/communication pass-through (202) may include one or more such contacts.

### B.2 External Regulated Output(s)

A DC-DC converter (210) derives a regulated 5 V rail from the VBAT pass-through (201). The 5 V rail may feed: (i) a USB-A receptacle (154) via node 214 with a BC1.2 identification network (213) (for example, shorting D+ to D− for a DCP profile or other standards-compliant indication), and/or (ii) a USB-C source receptacle (156) via node 216 with USB-C CC pull-up(s) (212) (Rp) to advertise a source current level (for example, default, 1.5 A, or 3.0 A). Presence or absence of USB Power Delivery (PD) negotiation on any output is non-limiting. (Node-to-port association for FIG. 7: 214->154; 216->156; 220->152.)

### B.3 Optional USB-In Charging

In some embodiments the interposer accepts external power via a USB-C sink receptacle (152) coupled at node (220) with CC pull-down(s) (212) (Rd) and routes that input to a generic CC/CV charger (230). The charger outputs to the VBAT rail through a unidirectional element (240) (for example, an ideal-diode FET arrangement) and an OR-ing element (242) to prevent reverse current and permit coexistence of the external input and the attached battery without requiring active source-priority control. Output current allocation depends on instantaneous rail voltages and charger state.

### B.4 Protections and ESD (Optional)

Protections (250) such as over-voltage, over-current, short-circuit, inrush limiting, and reverse-polarity protection may be implemented discretely or within functional ICs. ESD arrays (252) at the receptacles (152, 154, 156) are optional. No external temperature sensor is required; an external temperature sensor may optionally be provided.

### B.5 Indicators

The interposer includes two LED indicators (180) (green) and (181) (red) visible via apertures (182) and (183). In a representative implementation, the indicators illuminate only when external power is present at the sink port (152); when present: green ON/red OFF indicates that no battery is connected or that a connected battery is fully charged, and red ON/green OFF indicates that a connected battery is charging. This behavior may be produced by passive detection of sink presence and charger status outputs.

### C. Adaptation to Different Radio Models

Although figures reference a Motorola CP200/CP200d-type geometry, the interposer is not limited to any particular radio family. The interfaces (111/112) can be dimensioned to mate with the battery interface of a selected radio and the complementary battery pack while maintaining: (i) the pass-through rails (201/202), (ii) at least one user-accessible regulated output (for example, USB-A and/or USB-C), and (iii) in some embodiments, a USB input interface (152) and charge path (230 with 240/242) configured to deliver charging current to the attached battery through the pass-through power path (201). Alternative tab/latch geometries, contact styles (for example, pogo, leaf, spring), and port placements are within the scope.

### D. Best Mode

At the time of filing, a representative best-mode implementation includes: USB-A (154) and USB-C (156) 5 V outputs provided by 210, a USB-C sink (152) feeding a charger (230) via 212 (Rd), and output to the VBAT rail through 240/242. Indicators (180/181) operate as described herein. Other embodiments omit charging (5 V-out only). PD capability on outputs is optional.

### E. Variations and Conventions

Unless otherwise indicated, singular forms include plural referents and vice versa. The terms “comprising,” “including,” and “having” are used in an open sense and do not exclude additional elements or steps. Features described with respect to one embodiment may be combined with features of other embodiments unless clearly incompatible. Positional and dimensional data (for example, thickness, placement) are exemplary and non-limiting. References to standards (for example, USB Type-C, BC1.2) encompass compliant or functionally equivalent implementations.

1. An interposer for a two-way radio, comprising: a housing having a first interface configured to mate with a two-way radio and a second interface configured to mate with a removable battery for the radio; contacts at the interfaces that define a pass-through power path between the battery and the radio; and power-conversion circuitry configured to provide a regulated external output to a user-accessible connector.

2. The interposer of claim 1, wherein the user-accessible connector comprises a USB Type-A receptacle and the regulated external output is approximately 5 V.

3. The interposer of claim 1, wherein the user-accessible connector comprises a USB Type-C receptacle operable in a source mode with a CC pull-up that advertises an available source current level.

4. The interposer of claim 1, wherein the interposer further comprises a USB input interface and a charge circuit configured to receive external power and deliver charging current to the battery via the same terminals that define the pass-through power path.

5. The interposer of claim 4, wherein the charge circuit comprises a constant-current/constant-voltage charger and a unidirectional element arranged with an OR-ing element to permit coexistence of an external input and the battery while preventing reverse current into the input.

6. The interposer of claim 1, wherein the auxiliary communication contact is passed through without termination, biasing, or signal conditioning by the interposer.

7. The interposer of claim 1, wherein the user-accessible connector comprises the USB Type-A receptacle and includes a BC1.2-type identification network on D+ and D−.

8. The interposer of claim 3, wherein the CC pull-up advertises a current level selected from default, 1.5 A, and 3.0 A.

9. The interposer of claim 1, further comprising indicators visible at an exterior surface of the housing, the indicators configured to convey charging status.

10. The interposer of claim 9, wherein the indicators comprise a green LED and a red LED that illuminate only when external power is present at a sink port, with red indicating charging and green indicating a fully charged or absent battery.

11. The interposer of claim 1, further comprising electrostatic discharge protection coupled to at least one of the user-accessible connectors.

12. The interposer of claim 1, wherein the housing includes tabs and a spring latch with a thumb release configured to retain the battery to the interposer and the interposer to the radio.

13. The interposer of claim 1, wherein USB Power Delivery negotiation is omitted on the user-accessible connector.

14. The interposer of claim 1, wherein the user-accessible connector further comprises USB Power Delivery capability.

15. The interposer of claim 1, wherein the first and second interfaces are dimensioned to mate with a battery interface of a Motorola CP200 or CP200d radio.

16. The interposer of claim 1, wherein the regulated external output is provided by a buck converter that derives the regulated voltage from the pass-through power path.

17. The interposer of claim 4, wherein the USB input interface comprises a USB Type-C receptacle having at least one CC pull-down resistor.

18. The interposer of claim 1, wherein the user-accessible connector is disposed on an exterior surface of the housing.
